(19) United States
(12) Patent Application Publication
(10) Pub. No.: US 2012/0152327 A1
(43) Pub. Date: Jun. 21, 2012

(54) METHOD OF MANUFACTURING SOLAR MODULES

(75) Inventors: Mustafa Pinarbasi, Morgan Hill, CA (US); Louis DiNardo, San Francisco, CA (US); Donald E. Rudolfs, San Jose, CA (US)

(73) Assignee: SoloPower, Inc., San Jose, CA (US)

(21) Appl. No.: 13/333,954

(22) Filed: Dec. 21, 2011

Related U.S. Application Data
(63) Continuation-in-part of application No. 12/945,759, filed on Nov. 12, 2010.

(51) Int. Cl. H01L 31/048; H01L 31/18

(52) U.S. Cl. 136/251; 438/66; 257/E31.117

(57) ABSTRACT

A solar cell module that has a back protective sheet and a front transparent protective sheet and edge sealant members that seal an inner portion of the solar cell module so as to define a cavity that receives a plurality of solar cells. A portion of the back protective sheet extends beyond the sealant members so as to define a mounting region that can receive mounting structures such as holes, connectors, rails or the like. By providing the mounting region, the mounting structures can be spaced from the sealant members which limits the damage to the sealant members during the mounting process and preserves the moisture sealed state of the solar cell cavity.

### RELATED APPLICATIONS

This application is a continuation-in-part of U.S. patent application Ser. No. 12/945,759 entitled Flexible Solar Shell and Support Structure for Use with Rooftops which was filed Nov. 12, 2010 and is hereby incorporated by reference in it's entirety. This application is also related to U.S. Application No. ______(Atty Docket No. SPOW.013A2) entitled INTEGRATED STRUCTURAL SOLAR MODULE AND CHASSIS and U.S. Application No. (Atty Docket No. SPOW.011A) entitled JUNCTION BOX ATTACHMENT FOR PHOTOVOLTAIC THIN FILM DEVICES.

### BACKGROUND

1. FIELD OF THE INVENTIONS

The aspects and advantages of the present inventions generally relate to apparatus and methods of photovoltaic or solar module design and fabrication and, more particularly, to roll-to-roll or continuous packaging techniques for flexible modules employing thin film solar cells.

2. DESCRIPTION OF THE RELATED ART

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Standard silicon, CIGS and amorphous silicon cells can be fabricated on conductive substrates such as aluminum or stainless steel foils. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits can then be packaged in protective packages to form modules. Each module typically includes a plurality of solar cells which are electrically connected to one another. Many modules can also be combined to form large solar panels. The solar modules are constructed using various packaging materials to mechanically support and protect the solar cells contained in the packaging against mechanical damage.

In general, solar panels are placed on rooftops, often on roof shingles or other varieties of rooftop structures, to directly expose them to unobstructed sunlight. The modules are either directly secured onto the rooftops or onto a rack secured onto the rooftops. However considering most solar panels are installed on rooftops in large numbers, installers often attach the panels to underlying roof support structures using various fasteners, for example, adhesives or conventional fasteners. During the installation such fasteners physically contact the moisture sealed body of a conventional module. As a result, they can potentially damage the module during the installation. Such installation approaches also further complicates replacements and maintenance of the solar panels that are, in some cases, permanently anchored to the roof support structures. Since the solar panels are permanently attached to the rooftop, any maintenance work can result in damaging the module and the rooftop.

From the foregoing, there is a need in the solar cell industry, especially in thin film photovoltaics, for improved solar module designs that result in easy to maintain solar modules so that replacements and repairs can be performed in short time and reduced cost. Such techniques should not require alterations in the existing rooftop structure.

### SUMMARY

The aforementioned needs are addressed by the present invention which in one aspect comprises a solar module, comprising a back protective sheet including an inner section surrounded by an edge section, wherein the edge section extends between the edge of the back protective sheet and the inner section. The solar module further comprises a transparent front protective sheet disposed above a top surface of the inner section of the back protective sheet, wherein the front protective sheet having the size and shape of the top surface of the inner section. In this aspect the solar module further comprises a peripheral sealant wall surrounding the inner section and extending between the edge of the front protective sheet and the edge of the inner section of the back protective sheet so as to form a module cavity on the inner section of the back protective sheet and a plurality of interconnected solar cells disposed within the module cavity so that a light receiving side of each solar cell faces the front protective sheet and a back side of each solar cell faces the back protective sheet. The solar module in this aspect further comprises a transparent support material that fills a remainder of the module cavity and surrounds the plurality of solar cells.

In another aspect the present invention comprises a method of manufacturing a solar module, comprising the steps of providing a back protective sheet including an inner section surrounded by an edge section, wherein the edge section has a predetermined width extending between the perimeter of the back protective sheet and the inner section and forming a module stack on a top surface of the inner section. Forming a module stack in this aspect comprises the steps of forming a peripheral sealant wall on the top surface of the inner section, which surrounds the inner section; disposing a plurality of interconnected solar cells over the top surface of the inner section that is surrounded by the peripheral sealant wall, each solar cell including a front light receiving side and a back substrate side; covering the plurality of solar cells with a transparent support material on both the front light receiving side and the back substrate side that faces the top surface of the inner section; placing a transparent protective sheet over the peripheral sealant wall and the support material covering the plurality of interconnected solar cells to form a module stack, wherein the transparent protective sheet has the same shape and size as the top surface of the inner section; and heating the module stack to form the solar module on the back protective sheet.

In another aspect, the present invention comprises a solar module comprising a back protective sheet having a first peripheral dimension and an inner portion and a transparent front protective sheet disposed above a top surface of the inner portion, wherein the transparent front protective sheet defines a second peripheral dimension that is less than the first peripheral dimension so that at least a portion of the back protective sheets extends outward from the transparent front protective sheet so as to define a mounting region of the back protective sheet. In this aspect the solar module further includes a peripheral sealant wall surrounding the inner portion of the back protective sheet, wherein the peripheral sealant wall is interposed between the mounting region and the inner portion and wherein the peripheral walls interconnect the back protective sheet and the transparent front protective sheet so as to define a module cavity in the inner potion of the back protective sheet and a plurality of interconnected solar cells positioned within the module cavity.

These and other aspects and advantages of the present invention will become more apparent from the following description taken in conjunction with the accompanying drawings.

### BRIEF DESCRIPTION OF THE DRAWINGS

FIG. 1 is a schematic view a thin film solar cell;

FIG. 2A is a schematic top view of an embodiment of a solar module including an edge section;

FIG. 2B is a schematic side view of a back protective sheet of the solar module shown in FIG. 2A;

FIG. 2C is a schematic side view of the solar module shown in FIG. 2A;

FIG. 3 is a schematic top view of the solar module shown in FIG. 2A including a treatment zone at the edge section;

FIG. 4A is a schematic view of a method of constructing a solar module structure in a lay-up station;

FIG. 4B is a schematic view of a method of laminating the module structure in a laminator to form a solar module;

FIG. 4C is a schematic view of a method of edge treating the module in a module edge treatment station; and

FIGS. 5A-5C are schematic illustrations of various edge treatment embodiments;

### DETAILED DESCRIPTION OF THE PREFERRED EMBODIMENTS

The preferred embodiments described herein provide solar cells and methods of manufacturing a photovoltaic module including one or more thin film solar cells, preferably including Group IBIIIAVIA compound solar cells. Preferably, a flexible polymer sheet, or a flat and flexible polymer sheet, or a flat and flexible polymer sheet including a moisture barrier layer such as a metallic layer or an insulator layer, is used to as a back protective sheet of the solar module. Specifically, the module including a plurality of interconnected thin film solar cells is built over an inner section of the back protective sheet that is surrounded by an edge section of the back protective sheet. The module is built by: applying a module edge sealant along the borders of the inner section and thereby forming a module cavity on the inner section that excludes the edge section of the back protective sheet; placing a plurality of interconnected solar cells within the module cavity and covering the interconnected solar cells with a support material such as an encapsulant material; finally, sealing the module cavity by placing a transparent front protective sheet on the module edge sealant. The transparent front protective sheet may have the size and shape of the top surface of the inner section. The edge section surrounding the module forms a shelf or extension of the solar module and is used to mount the solar module or panel on a surface by applying various fastening or capturing means to the edge section but not the sealed module itself or its sealed perimeter. The edge section may be mechanically or chemically treated or modified to include holes, fasteners or rails, or the like, or a combination of them, to assist mounting the solar module on a support structure such as rooftops or support racks. In one implementation one or more additional layers having the same size and shape of, or larger than, the back protective sheet may be attached to at least a portion of a back surface of the back protective sheet to further support it.

FIGS. 2A and 2C show an embodiment of a module 100 of the present invention in schematic plan view and in side view, respectively. As will be described more fully below, the module 100, shown in FIGS. 2A and 2C, is a laminated module. The module 100 includes solar cells 102 in a sealed module shell 104 that is formed by a back protective sheet 106, a transparent front protective sheet 108 and a peripheral edge sealant 110 extending between the back protective sheet and the front protective sheet. As also specifically illustrated in FIG. 2B in side view, the back protective sheet 106, having a top surface 106A and a bottom surface 106B, includes an inner section 107A and an edge section 107B. The edge section 107B may fully or partially surround the inner section 107A and may have a width in the range of 0.5 cm to 10 cm, preferably 1-4 cm extending between the border of the inner section and the edge of the back protective sheet. Depending on the application needs, the width of the edge section 107B may or may not be uniform around the inner section 107A. In this embodiment, the inner section 107A and the edge section 107B are integral parts of the back protective sheet 106; however, they may be made of different materials, which may be subsequently combined to form a single back protective sheet piece.

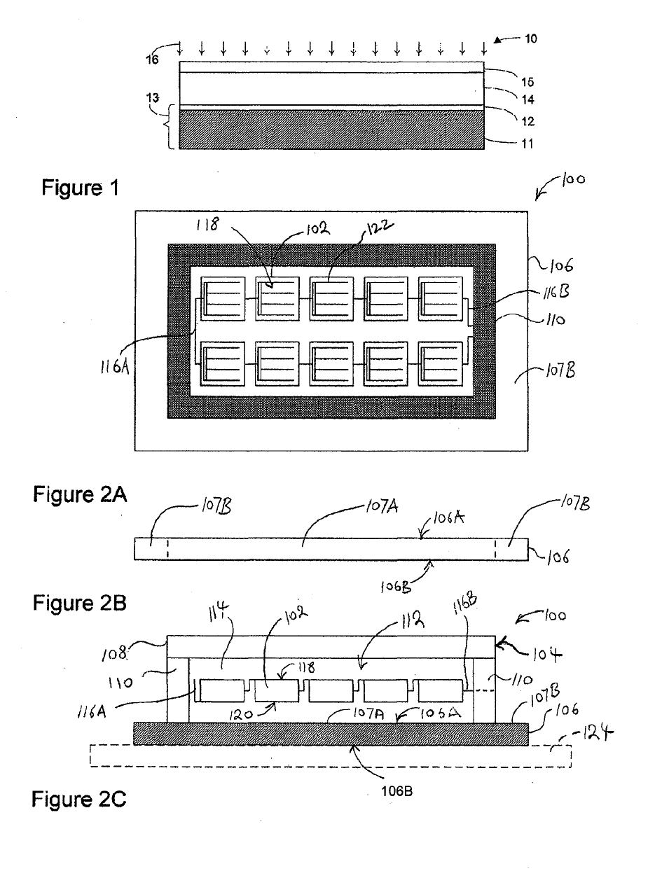

As shown in FIG. 2C, the peripheral edge sealant 110 is applied onto the top surface 106A to form a module cavity 112, or an inner space, over the inner section 107A on the top surface 106A. The peripheral edge sealant 110 is applied along the border between the inner section 107A and the edge section 107B excluding the edge section 107B. Solar cells 106 in the module cavity 112 may be covered or coated with a transparent support material 114 such as an encapsulant which fully or partially covers or coats the solar cells 102. The transparent front protective sheet 108 of the module is placed on the peripheral edge sealant 110 and the support material 114. Each solar cell 102 may be a thin film solar cell such as CIGS compound solar cells, silicon based solar cell or any other solar cell. In the preferred embodiment, the solar cells 102 are CIGS solar cells that are examplified in FIG. 1 described in the background section. In this embodiment, the solar cells are interconnected as an electrical circuit or string by interconnecting the solar cells 102 in series using conductive wires 116A by a process referred to as stringing. However, the solar cells 102 may be interconnected using a shingling process as described above in the background section. In the module 100, a light receiving side 118 of the solar cells 102 face towards the transparent front protective sheet 108 and a substrate side 120 facing towards the back protective sheet 106. The light receiving side 118 of the solar cells 102 includes a conductive grid 122 or terminal to collect current from the light receiving side 118. One more output wires 116B connect the circuit including the solar cells 102 to an outside junction box (not shown) which can in turn be used to connect the solar module to a power circuitry. A junction box may be attached on an edge section portion that may preferably be adjacent the location of the output wires 116B. As shown in FIG. 2C, optionally, one or more sheet support materials 124 may be attached or adhered to bottom surface 106B of the back protective sheet 106 to provide additional strength to the back protective sheet. The sheet support material 124 may have the same size and shape as the back protective sheet or larger than the back protective sheet 106.

An examplary material for the back protective sheet 106 may be a sheet of glass or a flexible polymeric sheet including for example polyvinyl fluoride (PVF) under TEDLAR® commercial name. The back protective sheet 106 may also comprise stacked sheets comprising polymeric sheets with various material combinations such as metallic films as moisture barrier. The transparent front protective sheet 108 may also include glass or a flexible polymeric sheet such as ethylene tetrafluoroethylene (ETFE) under TEFZEL® commercial name or fluorinated ethylene propylene (FEP). The transparent support material 114 or the encapsulant may include ethylene vinyl acetate copolymer (EVA) or thermoplastic polyurethanes (TPU). The peripheral sealant wall 110 may include butyl rubber with desiccants. The water vapor transmission rate of the module of the present invention may be 10⁻³gram/m²/day or less.

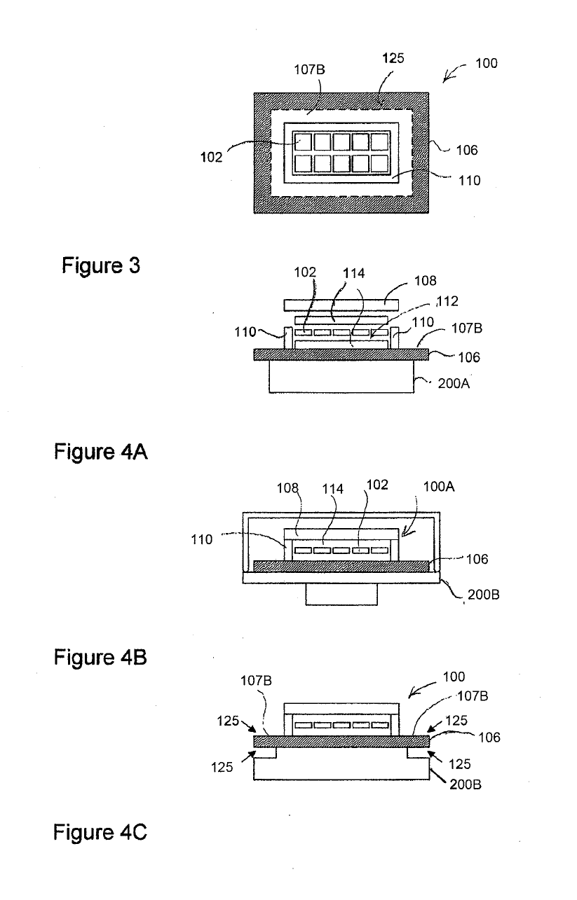

As shown in FIG. 3, the module 100 may have a treated zone 125 surrounding the edge section 107B. The treated zone 125 may extend along both the top surface and the bottom surface of the edge section 107B as in the manner shown in FIG. 3. The module 100 is held or captured using the treated zone 125 when placed on a support structure such as rooftops or support racks. Since the treated zone 125 is located away from the peripheral module sealant 110, the sealed shell 104 of the module 100 (FIG. 2C) is less likely to be accidentally damaged during the installation and operation of the module. The treated zone 125 may be formed by mechanically or chemically treating or modifying the edge section 107B to form various openings or structures to assist mounting the solar module on a support structure such as rooftops or support racks. The treated zone 125 may include one or more fasteners attached to the treated zone, such as clamps or the like to assist mounting the solar module on a support to capture the support. The treated zone 125 may also include one more auxiliary structures to assist mounting the solar module on a support structure, such as rails or the like protruding structures that can be held by a support structure. Various conventional fastening members such as nails, screws or adhesives may also be applied to top or back surface in the treated zone 125.

FIGS. 4A-4C illustrate an examplary method of manufacturing the module 100 of the present invention. As shown in FIG. 4A, in a lay-up station 200A, a module structure 100A or stack is first formed by applying the peripheral module sealant 110 on the inner section 107A of the back protective sheet 106 and forming a module cavity 112. Between the layers of support material 114, the solar cells 102, which are interconnected, are disposed within the module cavity 112, and in the following step the transparent front protective sheet 108 of the module is placed on the peripheral edge sealant 110 and the support material 114. As shown FIG. 4B, the module structure 100A formed on the back protective sheet 106 is then placed into a chamber of a laminator 200B, preferably a vacuum laminator. The module structure 100A is processed in the vacuum laminator by application of heat. During the lamination process, the support material 114 of the module structure 200A adheres to the interconnected solar cells and to the back and front protective sheets 106 and 108. The peripheral edge sealant 110 also adheres to the back and front protective sheets 106 and 108 sealing the module.

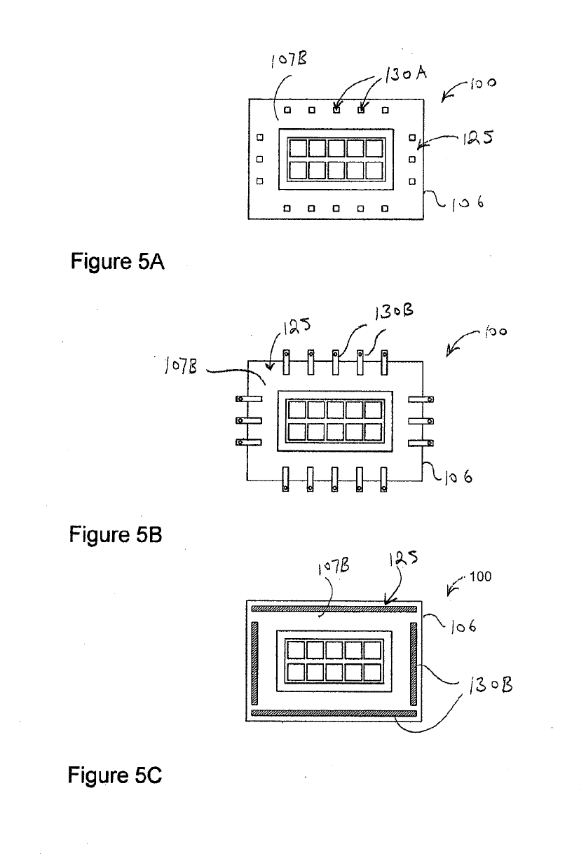

As shown in FIG. 4C, after the lamination process, the treated zone 125 at the edge section 107B of the module 100 may be formed at a module edge preparation station 200C. As shown in FIG. 5A in one embodiment, a number of holes 130A formed through the treated zone 125. As shown in FIG. 5B, The treated zone 125 may include one or more fasteners 130B attached to the treated zone 125, such as clamps or the like to assist mounting the solar module on a support. As shown in FIG. 5C, the treated zone 125 may include rails 130C or the like protruding structures that can be held by a support structure or support structure components.

Although aspects and advantages of the present inventions are described herein with respect to certain preferred embodiments, modifications of the preferred embodiments will be apparent to those skilled in the art. The scope of the present invention should not be limited to the foregoing discussion but should be defined by the appended claims.

What is claimed is:

1. A solar module, comprising:
a back protective sheet including an inner section surrounded by an edge section, wherein the edge section extends between the edge of the back protective sheet and the inner section;
a transparent front protective sheet disposed above a top surface of the inner section of the back protective sheet, wherein the front protective sheet having the size and shape of the top surface of the inner section;
a peripheral sealant wall surrounding the inner section and extending between the edge of the front protective sheet and the edge of the inner section of the back protective sheet so as to form a module cavity on the inner section of the back protective sheet;
a plurality of interconnected solar cells disposed within the module cavity so that a light receiving side of each solar cell faces the front protective sheet and a back side of each solar cell faces the back protective sheet; and
a transparent support material that fills a remainder of the module cavity and surrounds the plurality of solar cells.

2. The module assembly of claim 1, wherein one or more holes formed through the edge section of the back protective sheet to assist mounting the solar panel, wherein the holes formed between the edge of the back protective sheet and the peripheral seal wall so as not to damage the peripheral sealant wall.

3. The module assembly of claim 1, wherein one or more connector members are attached along the perimeter of the edge section of the back protective sheet to assist mounting the solar module, wherein at least one of the connector members is attached to a support structure during mounting of the solar module.

4. The module assembly of claim 1, wherein one or more rails attached along the perimeter of the edge section of the back protective sheet to assist mounting the solar module, wherein at least one of the rails is captured by the support structure during the mounting.

5. The module assembly of claim 1, wherein the width of the edge section is in the range of 0.5 mm-100 mm.

6. The module assembly of claim 1, wherein the width of the edge section is in the range of 10 mm-50 mm.

7. A method of manufacturing a solar module, comprising the steps of:
providing a back protective sheet including an inner section surrounded by an edge section, wherein the edge section has a predetermined width extending between the perimeter of the back protective sheet and the inner section;
forming a module stack on a top surface of the inner section, comprising the steps of:
forming a peripheral sealant wall on the top surface of the inner section, which surrounds the inner section;
disposing a plurality of interconnected solar cells over the top surface of the inner section that is surrounded by the peripheral sealant wall, each solar cell including a front light receiving side and a back substrate side;
covering the plurality of solar cells with a transparent support material on both the front light receiving side and the back substrate side that faces the top surface of the inner section;
placing a transparent protective sheet over the peripheral sealant wall and the support material covering the plurality of interconnected solar cells to form a module stack, wherein the transparent protective sheet has the same shape and size as the top surface of the inner section; and
heating the module stack to form the solar module on the back protective sheet.

8. The method of claim 7 further comprising the step of treating the edge section to form one more holes through the edge section of the back protective sheet to assist mounting the solar module, wherein at least one of the holes is captured by a support structure during mounting of the solar module.

9. The method of claim 7 further comprising the step of treating the edge section to attach one or more connector members along the perimeter of the edge section of the back protective sheet to assist mounting the solar module, wherein at least one of the connector members is attached to a support structure during mounting of the solar module.

10. The method of claim 7 further comprising the step of treating the edge section to attach one or more rails along the perimeter of the edge section of the back protective sheet to assist mounting the solar module, wherein at least one of the rails is captured by the support structure during the mounting.

11. A solar module comprising:
a back protective sheet having a first peripheral dimension and an inner portion;
a transparent front protective sheet disposed above a top surface of the inner portion, wherein the transparent front protective sheet defines a second peripheral dimension that is less than the first peripheral dimension so that at least a portion of the back protective sheets extends outward from the transparent front protective sheet so as to define a mounting region of the back protective sheet;
a peripheral sealant wall surrounding the inner portion of the back protective sheet, wherein the peripheral sealant wall is interposed between the mounting region and the inner portion and wherein the peripheral walls interconnect the back protective sheet and the transparent front protective sheet so as to define a module cavity in the inner potion of the back protective sheet;
a plurality of interconnected solar cells positioned within the module cavity.

12. The module of claim 11, further comprising a transparent support material that fills a remainder of the module cavity and surrounds the plurality of solar cells.

13. The module of claim 11, further comprising mounting structures formed on the mounting region of the back protective sheet, wherein the mounting structures are spaced from the peripheral walls so as to inhibit breach of the peripheral walls when mounting of the module on a surface.

14. The module of claim 13, wherein the mounting structures comprise holes, connectors or rails.

15. The module of claim 11, wherein the mounting region extends about the entire periphery of the inner portion of the back protective sheet.

16. The module of claim 11, wherein the mounting region of the back protective sheet is formed from the same material as the inner portion of the back protective sheet.

17. The module of claim 11, wherein the mounting region has a width in the range of 0.5 mm-100 mm.

18. The module of claim 11, wherein the solar cells are Group IBIIIAVIA thin film solar cells.

19. The module of claim 11, wherein the back protective sheet includes a flexible polymer sheet.

20. The module of claim 11, wherein the transparent front protective sheet includes a flexible polymer sheet.
